(19) United States
(12) Patent Application Publication
(10) Pub. No.: US 2026/0202441 A1
(43) Pub. Date: Jul. 16, 2026

(54) PROBE CARD FOR A TESTING APPARATUS OF ELECTRONIC DEVICES

(71) Applicant: TECHNOPROBE S.P.A., Cernusco Lombardone (LC) (IT)

(72) Inventor: Flavio MAGGIONI, Cernusco Lombardone (LC) (IT)

(73) Assignee: TECHNOPROBE S.P.A., Cernusco Lombardone (LC) (IT)

(21) Appl. No.: 19/136,471

(22) PCT Filed: Dec. 14, 2023
(86) PCT No.: PCT/EP2023/085778

§ 371 Date: Jun. 6, 2025

(30) Foreign Application Priority Data
Dec. 21, 2022 (IT) 102022000026184

(51) Int. Cl. G01R 1/073; G01R 1/067

(52) U.S. Cl. CPC G01R 1/07342; G01R 1/06783

(57) ABSTRACT

A probe card configured to be mounted in a testing apparatus of electronic devices includes at least one probe head that houses a plurality of contact probes, each contact probe having at least one first end portion configured to abut onto contact pads of a device under test, as well as a main board and an intermediate board connected to the main board , the intermediate board being adapted to perform a distance spatial transformation between contact pads formed on opposite faces thereof and acting as a space transformer. The space transformer comprises at least one core made of a material having a thermal conductivity greater than 100 W/(m·K) to collect and dissipate a heat produced by the probe card during testing operations of the electronic device.

### DESCRIPTION

### Technical Field

The present invention relates to a probe card of a testing apparatus of electronic devices.

The invention relates particularly, but not exclusively, to a probe card comprising an intermediate board serving as a space transformer interposed between a plurality of contact probes and a plate for connection with a testing apparatus and the following description is made with reference to this field of application with the only purpose of simplifying the exposition thereof.

### Background Art

As it is well known, a probe card is essentially a device adapted to electrically connect a plurality of contact pads of a microstructure, in particular an electronic device integrated on a wafer, with corresponding channels of a testing apparatus which performs the test thereof.

The test performed on integrated devices is used in particular to detect and isolate defective devices as early as in the production phase. Normally, the probe cards are thus used for the electric test of the devices integrated on wafers or chips before cutting or singulating and assembling them inside a containment package.

A probe card comprises a probe head essentially including in turn a plurality of movable contact elements or contact probes provided with at least one contact end portion or tip configured to abut onto a corresponding plurality of contact pads of the device under test. The terms end or tip mean here and below an end portion of said probes, being not necessarily pointed.

It is well known that the efficacy and reliability of a measuring test depends, among other factors, on creating a good electric connection between the device under test and the testing apparatus, indeed, and thus, on establishing an optimum probe/pad electric contact.

Among the types of probe heads used in the here-considered technical field for testing devices integrated on wafers, the so-called vertical probe heads are widespread, in which the contact probes are arranged substantially perpendicular to a plane on which the device under test lies.

In particular, a vertical probe head comprises a plurality of contact probes retained by at least one plate or guide, usually by a pair of plates or guides, which are substantially plate-shaped and parallel to each other. Said guides are located at a certain distance from each other so as to leave a free space or air gap for the movement and possible deformation of the contact probes during the testing operations and they are provided with appropriate guide holes adapted to slidingly house said contact probes. More particularly, the pair of guides comprises an upper guide (upper die) and a lower guide (lower die), both equipped with guide holes through which the contact probes axially slide, usually made by wires of special alloys with good electric and mechanical properties and in the field also indicated as needles, the term lower conventionally indicating the guide which is closer to the device under test.

The good connection between the contact probes of the probe head and the contact pads of the device under test is ensured by pressing the probe head on the device itself, the contact probes, which are movable inside the guide holes made in the upper guide and lower guide, undergoing, during said pressing contact, a bending, inside the air gap between the two guides, and a sliding inside the guide holes housing them.

The bending of the contact probes in the air gap can be also helped and guided through a suitable configuration of the probes themselves or of the guides, using in particular pre-deformed contact probes or suitably transversely shifting the guides comprising them, the transverse direction being the one which is substantially parallel to the plane of the device under test and of the guides.

In general, probe heads with probes that are not fixedly fastened, but kept interfaced to an appropriate main board, connected in turn to the testing apparatus are used: in that case they are referred to as unblocked probe heads. Said main board is also indicated as main PCB, since it is usually made using the techniques of the printed circuits or PCB (“Printed Circuit Board”) , a technology that allows to form boards with active areas, that is provided with contact pads, being even large-sized, although with major limitations with respect to a minimum reachable value for the distance (pitch) between the centres of the contact pads and thus usually reserved just to form said main board, which has less stringent distance constraints between the pads than the device under test.

These less stringent distance constraints between the contact pads, and in particular the spacing of adjacent pads on the main board, are possible due to the use of an intermediate board or space transformer which has contact pads made on opposite faces thereof with centres at a different distance between a face and the opposite one, suitably connected with each other by means of connections, in particular metal tracks, made inside the space transformer itself.

In this case, the contact probes have a further end portion or contact head adapted to abut onto a plurality of contact pads made on a first face of said space transformer, in particular a face arranged towards the probe head and thus the device under test. The good electric contact between contact probes and space transformer is ensured similarly to the contact with the device under test by pressing the probes onto the contact pads made on the space transformer.

Furthermore, the main board is generally kept in place by means of a stiffener. The assembly of the probe head, of the main board, of the intermediate board or space transformer and of the stiffener forms a probe card, globally and schematically indicated with 10 in FIG. 1.

In particular, the probe card 10 thus comprises a probe head 1, in the figure example comprising a plurality of vertical probes 2 and at least one upper guide 4 and one lower guide 5, having respective upper guide holes 4A and lower guide holes 5A within which the contact probes 2 slide.

Each contact probe 2 has at least one first end portion or contact tip 2A which abuts onto a contact pad 3A of a device under test 3 integrated on a semiconductor wafer 3′, realising the mechanical and electric contact between the device under test and a testing apparatus (not represented) of which said probe head 1 forms an end element.

Moreover, each contact probe 2 has a second end portion, indicated in the field as a contact head 2B, the probe body 2C extending between the contact tip 2A and the contact head 2B along a longitudinal development axis of the contact probe 2, said longitudinal development axis being substantially orthogonal to a plane of the device under test and thus to the guides.

The contact head 2B is in turn configured to contact a plurality of contact pads 6A formed on an intermediate board, which serves in particular as a space transformer 6, and is connected to a main board 7, in turn connected to the actual testing apparatus.

The spatial transformation performed by the space transformer 6 involves in particular the distances between the centres of the contact pads formed on opposite faces thereof; said space transformer 6 comprises a first plurality of contact pads 6A formed on a first face FA thereof facing the probe head 1 at the contact heads 2B of the contact probes 2 and connected by suitable metallizations 6C to a second plurality of contact pads 6B formed on a second opposite face FB thereof facing the main board 7, said second plurality of contact pads 6B having a different spatial distribution, in particular with centres of the pads at a greater distance, i.e. greater pitches with respect to the pitch of the first plurality of contact pads 6A, which are instead distributed in a manner substantially corresponding to the contact pads 3A of the device under test 3. The space transformer 6 thereby performs the spatial transformation, with a spacing of the contact pads 6B formed on the second face FB thereof with respect to the contact pads 6A formed on the first face FA thereof. They are commonly referred to as probe side pads or fine pitch pads and as PCB side pads or large pitch pads to indicate the contact pads 6A of the first plurality and the contact pads 6B of the second plurality, respectively.

The good electric contact between contact probes 2 and space transformer 6 is ensured similarly to the contact with the device under test 3 by pressing the probes onto the contact pads 6A made on the first face FA of the space transformer 6.

As already indicated, the main board 7 is also kept in place by means of a stiffener 8, which is configured so as to make the whole assembly more rigid and resistant and allows the flatness defects to be reduced, in particular in relation to the space transformer 6, which has generally very reduced thicknesses and which has thus considerable flatness problems.

In the embodiment illustrated in FIG. 1, the probe head 1 comprises a further intermediate guide 5′ (medium guide), which is plate-shaped and parallel to the upper guide 4 and to the lower guide 5 and arranged therebetween, preferably close to the lower guide 5, the intermediate guide 5′ being in turn provided with a plurality of intermediate guide holes 5′A in which the contact probes 2 are slidingly housed.

Suitably, the upper guide 4, the lower guide 5 and the intermediate guide 5′ are shifted from each other, with respect to a transverse direction corresponding to the x axis of the local reference of FIG. 1, so as to ensure a preferential bending direction to the contact probes 2, besides a correct retention thereof inside the probe head 1, completed by a housing 9 which makes the guides integral with each other and encompasses the contact probes 2.

In the vertical probe technology, it is thus important to ensure the good connection of the contact probes with the device under test, in particular at their contact tips, and with the testing apparatus, in particular at their contact heads and thus at the space transformer, which plays a very important role especially in the testing operations of integrated circuits made according to the most recent integration technologies which provide for contact pads on the devices under test which are extremely close and very small in size, constraints which are not compatible with the PCB technology through which the main board of the probe card is formed.

The mutual positioning of the elements composing the probe card also turns out to be an extremely important parameter for a correct operation of the probe card itself and the different technologies used to make said elements introduce flatness problems which complicate the configuration of the probe card as a whole and especially in connection with the mutual positioning of the intermediate board or space transformer and main board. Even the presence of the stiffener, which makes the whole assembly more rigid and resistant, does not allow in general the flatness defects of the space transformer to be eliminated in a sufficient way and the correct and complete contact thereof with the main board to be ensured.

All the above is further complicated by the operating temperature of the probe card itself, in particular in case of testing operations at extreme temperatures. In that case, in fact, the thermal expansions of the elements composing the probe card can affect the correct behaviour thereof, in particular due to the different thermal expansion coefficients of the different materials of which said elements are made. It is in fact usual to bind together the elements composing a probe card by means of screws, which, in particular during temperature testing operations, apply to the different plates a constraint which tends to cause a buckle thereof, resulting in a malfunction of the probe card as a whole, to the limit even in the lack of contact of the contact probes of the probe head with the contact pads of the device under test.

This problem is particularly felt in case of large-sized probe cards, such as for example the probe cards for the testing operations of memory devices such as DRAMs. For this type of probe cards, the failure to control the thermal expansion of the components involves considerable problems during the testing phase.

Moreover, during the testing operations, the contact probes heat up due to the passage of the different signals, increasing the heat which is present inside the probe head, in particular in case of a probe head provided with a very high number of contact probes.

Similarly, the abutment of said contact probes onto the pads of the space transformer and the transport of the signals therein from the probe side pads to the PCB side pads produce an undesirable heat that accumulates in the probe card.

The technical problem of the present invention is to provide a probe card, having such structural and functional features as to allow to overcome the limitations and drawbacks still affecting the probe cards made with the known technologies, favouring the elimination of the heat which is produced during the testing operations and limiting the increase in the operating temperature of the probe card and the probe head contained therein.

### DISCLOSURE OF INVENTION

The solution idea underlying the present invention is to provide the space transformer of a probe card starting from a core made of a material having a high thermal conductivity, which is able to collect and dissipate the heat produced therein and inside the probe head connected thereto, said core being preferably selectable even with a stiffness which is sufficient to form a mechanical support for the space transformer as a whole as well.

Based on this solution idea the technical problem is solved by a probe card configured to be mounted in a testing apparatus of electronic devices, said probe card comprising at least one probe head that houses a plurality of contact probes, each contact probe having at least one first end portion configured to abut onto contact pads of a device under test, as well as a main board and an intermediate board connected to the main board, said intermediate board being configured to realize a distance spatial transformation between contact pads formed on opposite faces thereof and acting as a space transformer. Suitably, said space transformer comprises at least one core made of a material having a thermal conductivity greater than 100 W/(m·K) to collect and dissipate a heat produced by the probe card during testing operations of the electronic device.

More particularly, the invention comprises the following additional and optional features, taken individually or in combination, if needed.

According to an aspect of the invention, the core can be made of a material having a thermal conductivity greater than 500 W/(m·K).

According to another aspect of the invention, the core can be made of a non-conductive material.

More particularly, the core can be made of a material selected from silicon nitride, silicon carbide, CVD-D (Chemical Vapor Deposition-Diamond) and aluminum nitride.

Furthermore, the core can be made of a material having a value of the Young's modulus greater than 30000 MPa, preferably greater than 1200000 MPa.

According to another aspect of the invention, the core can comprise a plurality of through holes arranged so as to connect a first face and a second and opposite face of said core.

Furthermore, according to another aspect of the invention, the core can be formed by a plurality of layers of different materials.

According to yet another aspect of the invention, the space transformer can comprise a plurality of further layers made at at least one of the faces of the core, in any number greater than one and arranged symmetrically or asymmetrically with respect to the core itself.

According to another aspect of the invention, the space transformer can comprise the further layers only at a first face of the core, a second opposite face of the core being in direct thermal contact with the main board.

In particular, said further layers can be made of an organic material, the space transformer being in the form of an organic multilayer or MLO or of a metallic or ceramic material, the space transformer being in the form of a ceramic-based multilayer or MLC.

According to still another aspect of the invention, said further layers and said core can have transversal dimensions along a development plane of the device under test which are equal to each other.

As an alternative, the core can have at least one transversal dimension greater than the space transformer and comprise at least one peripheral portion exposed with respect to said space transformer.

According to another aspect of the invention, the probe card can further comprise conductive layers which coat the core and extend at the peripheral portion.

According to yet another aspect of the invention, the probe card can further comprise a heat dissipator that is thermally associated with the core at the peripheral portion.

The probe card can also further comprise heat-exchange structures configured to thermally connect the core with the main board.

In particular, said heat-exchange structures can be selected from active or passive screws or thermal pipes, in pressing contact, welded, glued by a thermal glue or joined by crimping to the core, preferably at the peripheral portion.

According to another aspect of the invention, the core can further comprise a microfluidic path for the passage of a cooling fluid.

In particular, said microfluidic path can comprise a plurality of microfluidic channels for the passage of the cooling fluid between a fluid inlet area and a fluid outlet area, said fluid inlet area and fluid outlet area being formed in the peripheral portion of the core.

Furthermore, said plurality of microfluidic channels can comprise a first group of microfluidic channels formed at the fluid inlet area and a second group of microfluidic channels formed at the fluid outlet area.

The features and advantages of the probe card according to the invention will become apparent from the following description of exemplary embodiments thereof given by way of non-limiting examples with reference to the attached drawings.

### BRIEF DESCRIPTION OF DRAWINGS

In the drawings:

FIG. 1 shows a schematic sectional view of a probe card made according to the prior art;

FIG. 2 shows a schematic sectional view of a probe card according to an embodiment of the invention;

FIGS. 3A-3D show respective schematic sectional views of a probe card according to alternative embodiments of the invention; and

FIGS. 4A-4B and 5A-5B show respective side and plan sectional views of a space transformer comprised in a probe card according to further alternative embodiments of the invention.

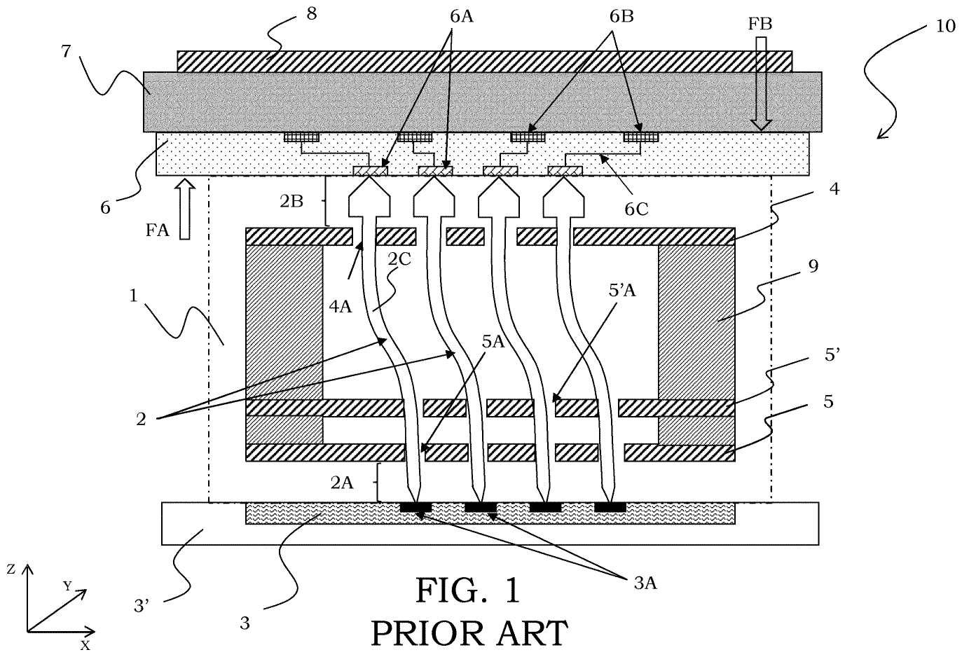

### MODES FOR CARRYING OUT THE INVENTION

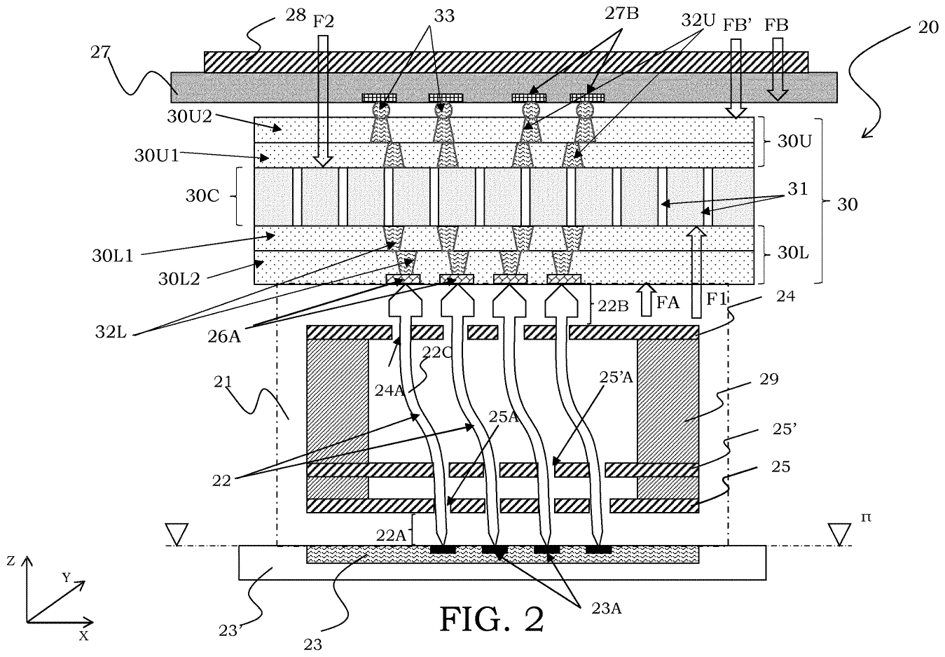

With reference to the figures, and particularly to FIG. 2, a probe card comprising at least one probe head provided with a plurality of contact probes for the test of electronic devices, in particular integrated on wafers, made according to the present invention is globally indicated with 20.

It should be noted that the figures represent schematic views of the probe card according to the invention and are not drawn to scale, but instead they are drawn so as to emphasize the important features of the invention.

Moreover, the several aspects of the invention represented by way of example in the figures are obviously combinable with each other and interchangeable from one embodiment to another.

In the following description, relative terms such as “above”, “below”, “upward”, “downward” will be used referring to the illustrations of the different elements given in the figures only to simplify the exposition thereof.

Finally, indications of particular geometries (circular, rectangular) or of the arrangement of the elements (parallel, orthogonal, contiguous) as well as the term “substantially” are always to be intended in connection with physical and not geometrically abstract elements, and thus they must always take into consideration the tolerances introduced by the transition from a pure mathematical/geometric world to the real world.

In particular, as illustrated in FIG. 2, the probe card 20 comprises a probe head 21 that houses a plurality of contact probes 22. The illustrated probe head 21 is of the unblocked probe vertical type and comprises at least one upper plate or guide 24 and one lower plate or guide 25, having respective upper guide holes 24A and lower guide holes 25A within which the contact probes 22 slide.

As it is conventional in the technical field of the present invention, the wording “lower guide” indicates the guide arranged closer to a device under test and the wording “upper guide” indicates the guide arranged closer to a testing apparatus connected to the probe card 20 that includes the probe head 21, when said probe card 20 and thus the probe head 21 is in the operating conditions, mounted like an end element of said testing apparatus.

The probe head 21 also comprises a containment element or housing 29, adapted to make the upper guide 24 and the lower guide 25 integral with each other and to encompass the contact probes 22.

In the example illustrated in FIG. 2, the probe head 21 also comprises an intermediate plate or guide 25′, arranged parallel between the upper guide 24 and the lower guide 25, in particular closer to the latter, the intermediate guide 25′ being similarly provided with intermediate guide holes 25′A through which the contact probes 22 slide. Said three-guide embodiment is merely given by way of example, the probe head 21 being allowed to comprise any number of guides which is greater or equal to one.

Each of the contact probes 22 comprises at least one first end portion or contact tip 22A configured to abut onto a corresponding contact pads 23A of a device under test 23, in particular integrated on a semiconductor wafer 23′, so as to establish the desired contact, in particular an electric contact, between the contact probes 22 of the probe head 21 and the contact pads 23A of the device under test 23.

Each contact probe 22 further comprises a second end portion or contact head 22B configured to establish the contact with a main board 27 or main PCB for connection with a testing apparatus (not illustrated). A rod-shaped probe body 22C is arranged between the contact head 22B and the contact tip 22A and substantially arranged along a longitudinal development direction of the contact probe 22, that is in particular orthogonal to a plane n on which the semiconductor wafer 23′ is arranged, where the device under test 23 is integrated, that is along the z axis of the local reference of FIG. 2.

The upper guide 24, the lower guide 25 and the intermediate guide 25′ are plate-shaped elements arranged parallel to each other and to the plane n of the semiconductor wafer 23′ and thus of the device under test 23. Suitably, as seen in connection to the prior art, said upper giode 24, lower guide 25 and intermediate guide 25′ are shifted from each other, with respect to a direction which is tangential to the plane n of the semiconductor wafer 23′ that is along the x axis of the local reference of FIG. 2, so as to impose a preferential bending direction to the contact probes 22. By virtue of this shift of the guides, the guide holes formed therein and housing a same contact probe turn out not to be aligned to each other with respect to a direction which is orthogonal to the plane n of the semiconductor wafer 23′, that is along the z axis of the local reference of FIG. 2, which forces a bending in the probe body 22C of the contact probes 22 and determines said preferential bending direction thereof.

The probe card 20 further comprises an intermediate board arranged between the probe head 21 and the main board 27 and configured to realise a spatial transformation, in particular in connection to the distribution of contact pads on the opposite faces thereof and for this reason indicated as a space transformer 30.

The space transformer 30 has a first face FA facing the probe head 21 (in the operating conditions, that is when the space transformer 30 is inserted in a probe card 20 comprising the probe head 21 and mounted as an end element of a testing apparatus), on said first face FA a first plurality of contact pads being formed, also indicated as probe side pads 26A, onto which the contact heads 22B of the contact probes 22 abut. Moreover, the space transformer 30 has a second face FB′ facing the main board 27 in the operating conditions.

Finally, the probe card 20 comprises a stiffener 28 associated with the main board 27 and adapted to improve the flatness thereof and to avoid the curvature thereof, in particular in case of an increase in temperature during the operation of the probe card 20, that is during the testing operations.

Advantageously according to the present invention, the space transformer 30 comprises a core 30C made of a material having a high thermal conductivity λ, that is greater than 100 W/(m·K), preferably greater than 500 W/(m·K). Said high thermal conductivity λ allows in particular to obtain an optimum collection and subsequent dispersion of the heat produced in the space transformer 30 during the testing operations of the probe card 20, also helping the collection and dispersion of the heat generated in the probe head 21 due to the connection of the contact probes 22 contained therein with said space transformer 30.

In a preferred embodiment, the core 30C is made of a non-conductive material, so as not to interfere with the electric operation of the space transformer 30.

Suitably, the core 30C is further made of a material having a high stiffness, that is a high value of the modulus of tensile elasticity or Young's modulus E, in particular greater than 30000 MPa, preferably greater than 1200000 MPa, so as to be a mechanical support for the space transformer 30, which comprises a plurality of layers suitably overlapping each other and the core 30C.

The core 30C can be made in particular of silicon nitride, silicon carbide or CVD-D (Chemical Vapor Deposition-Diamond), substantially dielectric materials, having a high thermal conductivity λ and having a stiffness which is sufficient to support the layers of the space transformer 30, in particular organic layers configured to form an organic multilayer (MLO).

In a preferred embodiment, the space transformer 30 is symmetrically formed around the core 30C and comprises a first portion, or lower portion 30L, formed at a first face F1, in particular a lower face of the core 30C, considering the local reference of FIG. 2 and a second portion or upper portion 30U, formed at a second opposite face F2, in particular an upper face of the core 30C, still considering the local reference of FIG. 2. The first face F1 of the core 30C is facing the device under test 23 when the probe card 20 is in the operating conditions, that is mounted as an end element of a testing apparatus (not shown) with the contact probes 22 of the probe head 21 arranged between the space transformer 30 and the device under test 23. The second face F2 of the core 30C is facing the main board 27, still when the probe card 20 is in the operating conditions.

More particularly, the upper portion 30U is arranged between the core 30C and the main board 27 and it is in contact with a plurality of pads 27B formed on a face FB of said main board 27 facing the device under test 23, when the probe card 20 is in the operating conditions. The lower portion 30L is instead arranged between the core 30C and the probe head 21 and it comprises a plurality of pads 26A formed on the first face FA of the space transformer 30 facing the device under test 23 when the probe card 20 is in the operating conditions, said plurality of pads 26A being in contact with the contact probes 22 of the probe head 21, in particular with the contact heads 22B of said probes.

In the example illustrated in FIG. 2, the upper portion 30U and the lower portion 30L of the space transformer 30 comprise both a pair of layers 30U1, 30U2 and 30L1, 30L2, respectively, but it is obviously possible to take into consideration a different number of layers, which is greater or equal to one for each portion as well as portions with a different number of layers the one from the other. Preferably, said layers 30U1, 30U2 and 30L1, 30L2 are made of an organic material, such as epoxy or polyimide, the space transformer 30 being thus an organic multilayer or MLO (Multi Layer Organic). As an alternative, the space transformer 30 is formed as a ceramic-based multilayer or MLC (Multi Layer Ceramic). The layers 30U1, 30U2 and 30L1, 30L2, of the upper portion 30U and of the lower portion 30L, respectively, have transversal dimensions, along the development plane n of the device under test 23 and of the guides, which are equal to each other and to the core 30C, in particular a same length along the x axis and a same depth along the y axis of FIG. 2. It is evident that the indication of “equal” dimensions, as well as the terms “plane”, “parallel” and “orthogonal” are always to be intended in connection with physical and not geometrically abstract elements, and thus they must always take into consideration the tolerances introduced by the transition from a pure mathematical/geometric world to the real world.

Suitably, the layers 30U1, 30U2 and 30L1, 30L2, which form the upper portion 30U and the lower portion 30L of the space transformer 30, are provided with respective conductive vias 32U and 32L, in contact with each other and able to form a conductive path from the pads 26A to the core 30C and from the core 30C to the pads 27B, respectively.

More particularly, conductive vias 32L of a first layer 30L1 of the lower portion 30L are in contact with conductive vias 32L of a second layer 30L2 of said lower portion 30L, in turn in contact with the pads 26A at the first face FA of the space transformer 30. Similarly, conductive vias 32U of a first layer 30U1 of the upper portion 30U are in contact with conductive vias 32U of a second layer 30U2 of said upper portion 30U, in turn in contact with the pads 27B at the second face FB′ of the space transformer 30.

Said conductive vias 32U, 32L are formed so as to space apart from each other starting from the pads 26A up to the pads 27B, so as to realize the desired spatial transformation, the pads 26A having centres with a distance (pitch) which is lower than the distance (pitch) of the centres of the pads 27B. Further conductive connecting structures 33, in particular conductive bumps, are formed at the second face FB′ of the space transformer 30 to create an electric connection between the conductive vias 32U of the layers of the upper portion 30U of said space transformer 30 and the pads 27B of the main board 27.

Advantageously according to the invention, the core 30C is further provided with a plurality of through holes 31 arranged so as to connect the first face F1 and the second face F2 of the core 30C itself. Said through holes 31 are in particular configured to transport a heat generated in the lower portion 30L and in the upper portion 30U of the space transformer 30 inside the core 30C, which provides for the redistribution thereof among all the through holes 31 which are present, so as to improve the efficiency of heat transport in a direction which is orthogonal to the core 30C, that is in a vertical direction along the z axis of FIG. 2. Furthermore, said heat is drained in a direction which is tangential with respect to the core 30C, that is in a horizontal direction along the x axis of FIG. 2, reaching an external edge of said core 30C, so as to ease the dispersion thereof, in particular in the air.

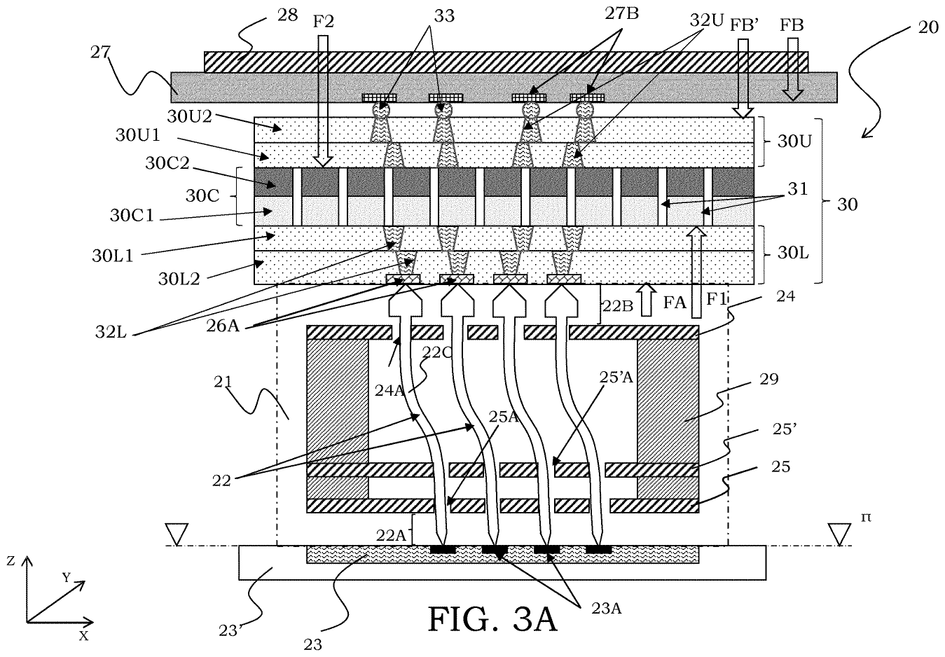

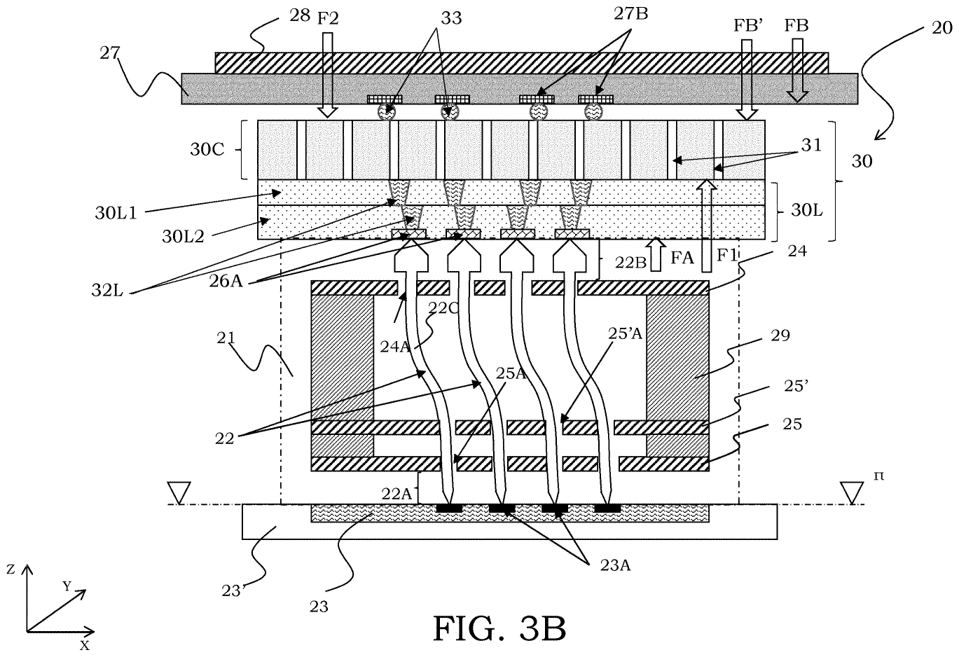

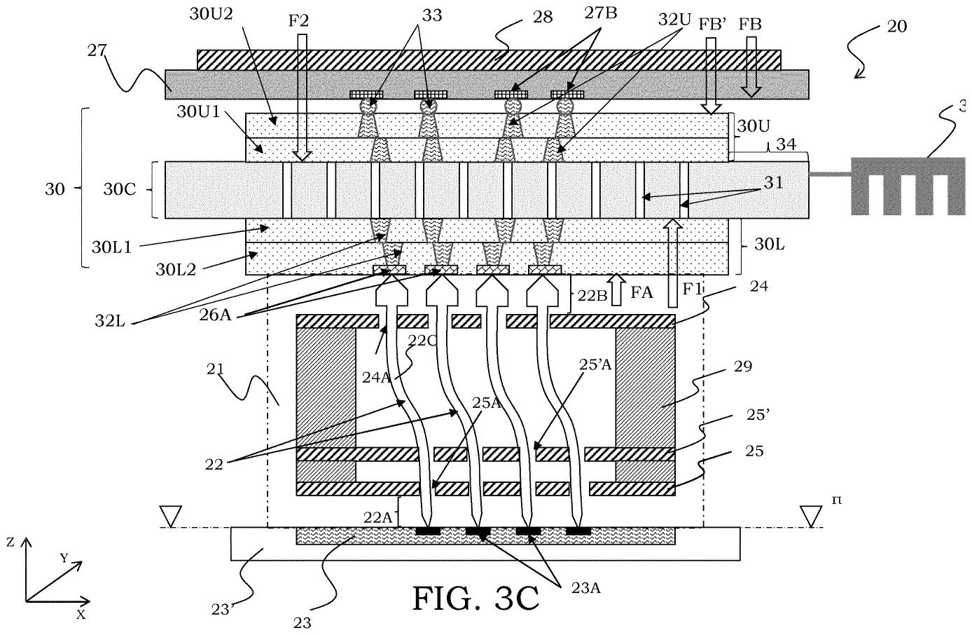

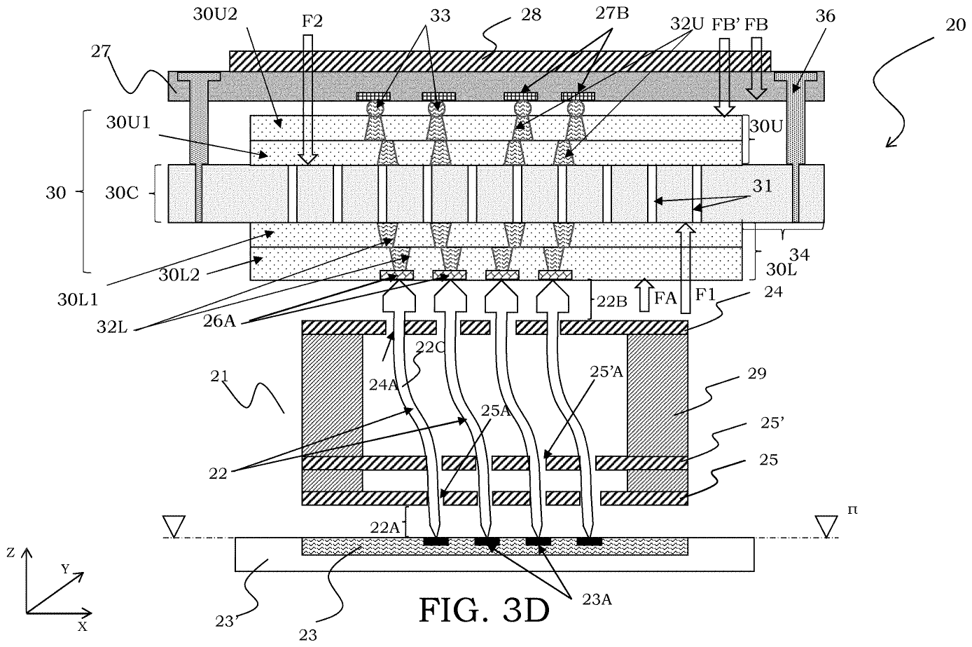

In an alternative embodiment, illustrated in FIG. 3A, the core 30C comprises a plurality of layers of different materials, in the illustrated example two layers, joined to each other, so as to improve the mechanical performances of said core 30C while ensuring a good level of heat exchange. Among the materials used to form the different layers of the core 30C silicon nitride, silicon carbide, CVD-D (Chemical Vapor Deposition-Diamond), and aluminum nitride may be considered, to name few.

Suitably, as will be explained hereinafter, the use of two layers made of different materials allows microfluidic channels to be manufactured along a horizontal direction, that is along the x axis of the figures, to obtain the desired cooling, but it also allows to limit the amount of coating with a material having a high thermal conductivity, such as CVD-D for example, with real advantages from the economic point of view, considering the costs of said materials, but also from a technological point of view, considering the problems tied to the maximum thickness value which can be obtained from the construction point of view.

In the embodiment illustrated in FIG. 3A, the core 30C comprises a first layer 30C1 of a first material and a second layer 30C2 of a second material, overlapping each other and joined to form said core 30C, said first and second layers 30C1, 30C2 having transversal dimensions which are equal to each other, particularly equal to each other and to the core 30C, that is having a same length along the x axis and a same depth along the y axis of FIG. 3A.

It is also possible to form the space transformer 30 with a structure which is not symmetrical with respect to the core 30C thereof. In that case, the space transformer 30 can comprise, for example, only the lower portion 30L associated with the core 30C at the first face F1 thereof, the core 30C being directly provided at the second face F2 thereof, coinciding with the second face FB′ of the space transformer 30, of the conductive connecting structures 33 for the contact with the pads 27B of the main board 27, as schematically shown in FIG. 3B. In that case too, the core 30C can be formed by more layers of different materials, for example two layers selected from silicon nitride, silicon carbide, CVD-D (Chemical Vapor Deposition-Diamond) and aluminum nitride, as explained above.

In the example illustrated in FIG. 3B, the layers 30L1 and 30L2 of the lower portion 30L have transversal dimensions which are equal to each other and to the core 30C, in particular a same length along the x axis and a same depth along the y axis of the local reference of FIG. 3B.

Suitably, according to this alternative embodiment, by using for the space transformer 30 a configuration in which the core 30C, which is a layer having a high thermal conductivity, is in direct thermal contact with the main board 27, the heat exchange through this main board 27 is maximized.

In a preferred alternative embodiment, the core 30C is formed so as to have a larger size than the space transformer 30, in particular a greater length along the x axis, as schematically shown in FIG. 3C. In the example illustrated in FIG. 3C, the core 30C is formed so as to have a larger size of the upper portion 30U and of the lower portion 30L comprised in the space transformer 30.

In particular, the core 30C comprises at least one peripheral portion 34 not in contact with, particularly not covered by, the space transformer 30, more particularly by the layers of the upper portion 30U and of the lower portion 30L of said space transformer 30, and thus exposed to air.

It is thus evident that the alternative embodiment of FIG. 3C increases the efficiency of heat dispersion, in particular in the air, realised by the space transformer 30 due to the presence of the peripheral portion 34. According to an alternative non-illustrated embodiment, conductive layers can be deposited on the opposite exposed surfaces of the core 30C, so as to possibly extend even at said peripheral portion 34, so as to further ease the heat dispersion. The peripheral portion 34 can also be possibly provided with through holes, so as to put the conductive layers which are present on the opposite surfaces thereof in communication with each other.

Suitably, according to the alternative embodiment illustrated in FIG. 3C, the probe card 20 can also comprise a heat dissipator 35 that is thermally associated with the core 30C, in particular at the peripheral portion 34 thereof.

As an alternative, as schematically illustrated in FIG. 3D, heat-exchange structures 36 can be provided, in the form of screws or thermal pipes which, passing through the main board 27, reach the core 30C, in particular at the peripheral portion 34 thereof, so as to convey the heat collected by said core 30C to the outside of the probe card 20. In other words, the heat-exchange structures 36 are able to thermally connect the core 30C with the main board 27, being in particular in pressing contact or possibly welded, glued by a thermal glue or also joined by seaming (crimping) to the core 30C, preferably at the peripheral portion 34 thereof.

Said heat-exchange structures 36 can be passive thermal pipes substantially in the form of rods of solid material, suitably a material having a high thermal conductivity λ, selected from a metallic or inorganic material, in particular a material having a thermal conductivity λ greater than 100 W/(m·K), preferably greater than 500 W/(m·K). Suitably, the heat-exchange structures 36 can be made of a material selected from copper, aluminum, aluminum nitride, silicon nitride, silicon carbide and CVD-D (Chemical Vapor Deposition-Diamond).

The heat-exchange structures 36 can be also formed by active thermal pipes essentially comprising an evaporation chamber, in which a liquid flows which is transformed into steam by the heat produced by the probe card 20 and is transported along each thermal pipe towards a condensation chamber, in which the steam is again transformed into liquid, releasing the heat to a suitable radiator, the liquid thus returning to the evaporation chamber to restart the process.

Finally, it is possible to form said heat-exchange structures 36 so as to comprise a reduced-diameter section, in particular along the core 30C, as in the example illustrated in FIG. 3D.

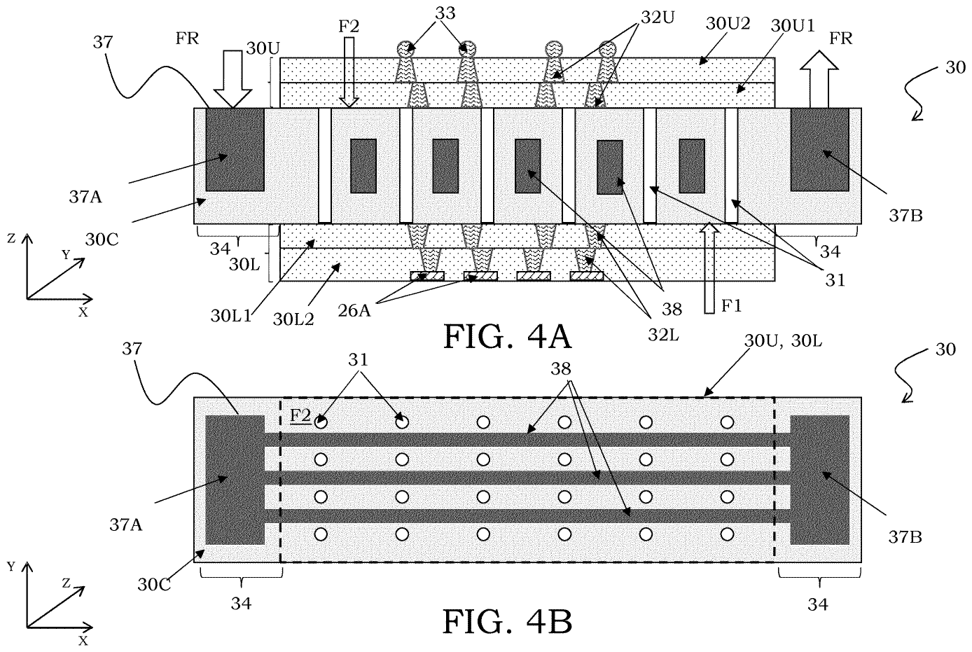

According to a further improving alternative embodiment, schematically illustrated in FIGS. 4A and 4B, the core 30C is provided with a microfluidic path 37 comprising a plurality of microfluidic channels 38 arranged between the through holes 31 and in connection between a fluid inlet area 37A and a fluid outlet area 37B, both made in the peripheral portion 34 of the core 30C.

Suitably, said microfluidic channels 38 can be formed by laser drilling. More particularly, the microfluidic channels 38 are preferably formed in areas in which the upper portion 30U and the lower portion 30L of the space transformer 30 are devoid of vias, so as to form preferential channels for the passage of a suitable cooling fluid FR which passes through the microfluidic path 37 from the fluid inlet area 37A to the fluid outlet area 37B.

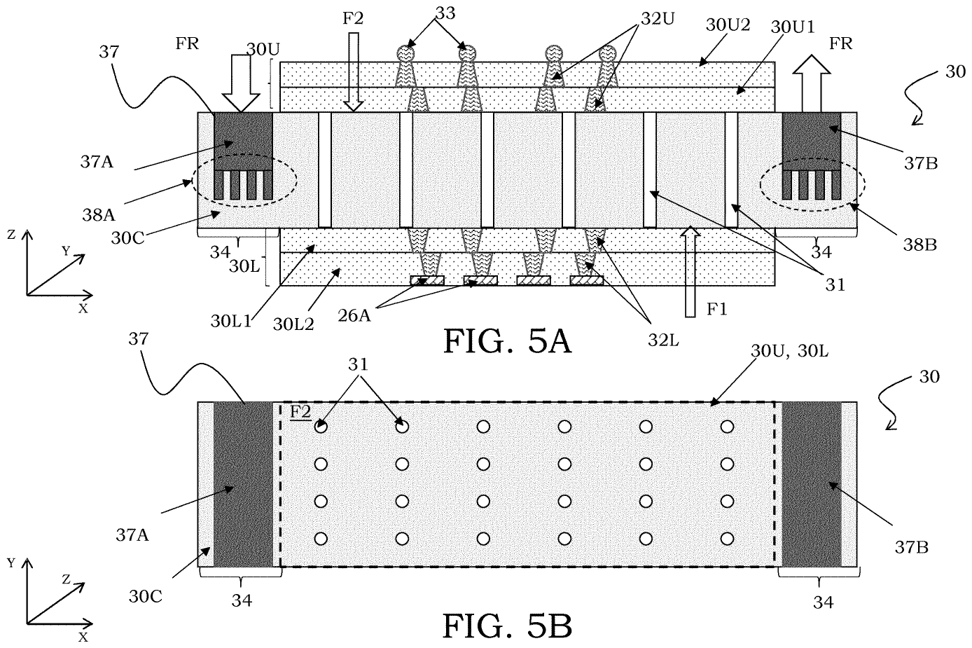

As an alternative, the microfluidic channels 38 can be formed only in the peripheral portion 34, in particular a first group 38A of microfluidic channels at the fluid inlet area 37A and a second group 38B of microfluidic channels at the fluid outlet area 37B, as schematically shown in FIGS. 5A and 5B.

The presence of the microfluidic path 37 allows to realize a liquid cooling which affects the whole space transformer 30 (in the embodiment of FIGS. 4A and 4B) or only the peripheral portion 34 thereof (in the embodiments of FIGS. 5A and 5B), which is able in any case to significantly improve the efficiency of the heat exchange realized by said space transformer 30, in particular by the core 30C thereof.

In conclusion, advantageously according to the invention, the probe card provided with a space transformer having a core made of a material having a high thermal conductivity is able to effectively disperse heat produced by the testing operations of an integrated device, especially in case of power signals. Suitably, the core turns out to be able to dissipate the heat produced therein but also the heat which is transmitted thereto by the contact probes of the probe head connected to said core during the operation thereof.

The probe card turns out thereby to be suitable for applications in which the testing operations considerably heat up the probe card as a whole, ensuring a correct operation thereof and avoiding any deformation of the elements composing it, deformation which could affect the good outcome of the testing operations.

The heat dispersion turns out to be further improved in the case in which the heat dissipation structure is associated with an additional heat dissipator or with a microfluidic path in which the cooling fluid is circulated.

Moreover, the core is suitably made of a material having a stiffness which is sufficient to form a mechanical support for the other layers as well, in particular organic ones, which form the space transformer.

Obviously, in order to meet contingent and specific requirements, a person skilled in the art will be allowed to bring several modifications and alternatives to the above-described probe card, all falling within the scope of protection of the invention as defined by the following claims.

1. A probe card configured to be mounted in a testing apparatus of electronic devices comprising
a probe head,
a plurality of contact probes housed into the probe head, each contact probe having a first end portion configured to abut onto contact pads of a device under test,
a main board, and
an intermediate board connected to the main board and adapted to realize a distance spatial transformation between contact pads formed on opposite faces thereof and acting as a space transformer,
wherein the space transformer comprises a core made of a material having a thermal conductivity greater than 100 W/(m·K) to collect and dissipate a heat produced in the probe card during testing operations of the electronic device.

2. The probe card according to claim 1, wherein the core is made of a material having a thermal conductivity greater than 500 W/(m·K).

3.-6. (canceled)

7. The probe card according to claim 1, wherein the core comprises a plurality of through holes configured to connect a first face and a second and opposite face of the core.

8. The probe card according to claim 1, wherein the core is formed by a plurality of layers of different materials.

9. The probe card according to claim 1, wherein the space transformer comprises a plurality of further layers made at a face of the core, in any number greater than one and arranged symmetrically or asymmetrically with respect to the core.

10. The probe card according to claim 9, wherein characterized in that the space transformer comprises the further layers only at a first face of the core, a second opposite face of the core being in direct thermal contact with the main board.

11. The probe card according to claim 9, wherein the further layers are made of an organic material, the space transformer being in the form of an organic multilayer MLO, a metallic or ceramic material, the space transformer being in the form of a ceramic-based multilayer MLC.

12. (canceled)

13. The probe card according to claim 9, wherein the further layers and the core have transversal dimensions along a development plane of the device under test which are equal to each other.

14. The probe card according to claim 1, wherein the core has a transversal dimension greater than the space transformer and comprises a peripheral portion exposed with respect to the space transformer.

15. The probe card according to claim 14, further comprising conductive layers which coat the core and extend at the peripheral portion.

16. The probe card according to claim 14, further comprising a heat dissipator that is thermally associated with the core at the peripheral portion.

17. The probe card according to claim 14, further comprising heat-exchange structures configured to thermally connect the core with the main board.

18. The probe card according to claim 17, wherein the heat-exchange structures are selected from the group consisting of: active and passive screws or thermal pipes, in pressing contact, welded, or glued by a thermal glue or joined by crimping to the core.

19. The probe card according to claim 1, wherein the core further comprises a microfluidic path for the passage of a cooling fluid.

20. The probe card according to claim 19, wherein the microfluidic path comprises a plurality of microfluidic channels for the passage of the cooling fluid between a fluid inlet area and a fluid outlet area and the core has at least one transversal dimension greater than the space transformer and comprises at least one peripheral portion exposed with respect to the space transformer, the fluid inlet area and fluid outlet area being formed in the peripheral portion of the core.

21. The probe card according to claim 20, wherein the plurality of microfluidic channels comprises a first group of microfluidic channels formed at the fluid inlet area and a second group of microfluidic channels formed at the fluid outlet area.
